(19) United States
(12) Patent Application Publication
(10) Pub. No.: US 2017/0268941 A1
(43) Pub. Date: Sep. 21, 2017

(54) TACTILE SENSING INTRUMENTED WAFER

(71) Applicant: GLOBALFOUNDRIES INC., Grand Cayman (KY)

(72) Inventor: Robert Boyd Finlay, Ballston Lake, NY (US)

(73) Assignee: GLOBALFOUNDRIES INC., Grand Cayman (KY)

(21) Appl. No.: 15/075,886

(22) Filed: Mar. 21, 2016

(51) Int. Cl. G01L 1/16; H01L 21/67

(52) U.S. Cl. CPC G01L 1/162; H01L 21/67253; H01L 21/67075; H01L 21/67092

(57) ABSTRACT

We disclose a tactile sensing instrumented wafer, which may comprise a substrate; and at least one tactile sensor array disposed on a top surface of the substrate. The at least one tactile sensor array may comprise carbon nanotubes or a piezoelectric transducer. In further embodiments, the instrumented wafer may further comprise a power supply; a memory; a communications interface; and a controller. An instrumented wafer in accordance with embodiments herein may detect both downforce and lateral forces impinging on the wafer, and may be used in a semiconductor device manufacturing system.

### BACKGROUND OF THE INVENTION

Field of the Invention

Generally, the present disclosure relates to the manufacture of sophisticated semiconductor devices, and, more specifically, to an instrumented wafer comprising a tactile sensor array.

Description of the Related Art

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (etching, doping, ion implanting, or the like), to the packaging and final testing of the completed device, are so different from one another and specialized that the processes may be performed in different manufacturing locations that contain different control schemes.

Generally, a set of processing steps is performed on a group of semiconductor wafers, sometimes referred to as a lot, using semiconductor-manufacturing tools, such as exposure tool or a stepper. As an example, an etch process may be performed on the semiconductor wafers to shape objects on the semiconductor wafer, such as polysilicon lines, each of which may function as a gate electrode for a transistor. As another example, a plurality of metal lines, e.g., aluminum or copper, may be formed that serve as conductive lines that connect one conductive region on the semiconductor wafer to another. In this manner, integrated circuit chips may be fabricated.

The set of processing steps may comprise one or more steps in which at least a first force impinges vertically on a wafer or lot. For example, chemical mechanical polishing (CMP) is frequently performed to clean and/or planarize wafer surfaces prior to the deposition of additional layers thereon. CMP typically involves a downforce and a lateral force applied to the wafer by a CMP pad. In addition, after CMP, a roller brush (commonly polyvinyl alcohol (PVA), polyvinyl chloride (PVC), or polypropylene (PP)) is often used to clean the wafer as the wafer enters a cleaner module after wafer polish/planarization. This roller brush also provides downforces on wafers. Downforces also impinge on wafers when dispensing photolithography developer solutions onto a wafer. Also, washing and drying steps are often performed on wafers. These steps typically involve high pressure liquid sprays and air flows (or flows of other gases). Further, inflow and exhaust of air or other gases into/from a processing chamber may also generate downforces on wafers.

As should be appreciated, given the nanometer scales of contemporary semiconductor device manufacturing processes, discrepancies between notional downforces and lateral forces and the actual forces impinging on the wafer can lead to over or under-polishing, incomplete washing, or incomplete drying of the wafer. Various negative effects may follow on from these results. For example, over-polishing a wafer by a CMP pad may lead to dishing of one or more components disposed on the wafer surface, and both over and under-polishing may lead to uneven wafer surfaces and subsequent uneven or incomplete deposition of further materials thereon.

Designers have attempted to implement instruments on wafers. Some of these instruments include temperature and/or vibration sensors. Also known is the use of such instrumented wafers for assessing actual conditions to which a wafer may be subjected during processing. However, known instrumented wafers lack the ability to detect both downforce and lateral forces impinging on the wafer.

The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to a tactile sensing instrumented wafer. In one embodiment, the present disclosure relates to an instrumented wafer, comprising a substrate; and at least one tactile sensor array disposed on a top surface of the substrate. The at least one tactile sensor array may comprise carbon nanotubes or a piezoelectric transducer. In further embodiments, the instrumented wafer may further comprise a power supply; a memory; a communications interface; and a controller.

An instrumented wafer in accordance with embodiments herein may detect both downforce and lateral forces impinging on the wafer.

### BRIEF DESCRIPTION OF THE DRAWINGS

The disclosure may be understood by reference to the following description taken in conjunction with the accompanying drawings, in which like reference numerals identify like elements, and in which:

FIG. 1A depicts in top-down view an instrumented wafer, in accordance with embodiments herein;

FIG. 1B depicts in side view an instrumented wafer, in accordance with embodiments herein;

FIG. 2 illustrates a semiconductor device manufacturing system comprising an instrumented wafer, in accordance with embodiments herein; and

FIG. 3 illustrates a flowchart of a method in accordance with embodiments herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for an instrumented wafer, comprising a substrate; and at least one tactile sensor array disposed on a top surface of the substrate. Some embodiments herein provide for the wafer to comprise a plurality of types of sensors, e.g., tactile sensors, vibration sensor, temperature sensor, etc., wherein data from the various sensor may be coordinated to determine one or more operation parameters, wafer condition, and/or feedback correction data. In some embodiments, the instrumented wafer may comprise a communication interface, a control, and/or memory to process data and/or provide a responsive action (such as provide feedback adjustment data, warning signals, etc.) Other embodiments herein provide for methods of using such an instrumented wafer; and semiconductor device manufacturing systems comprising such an instrumented wafer and capable of performing such methods.

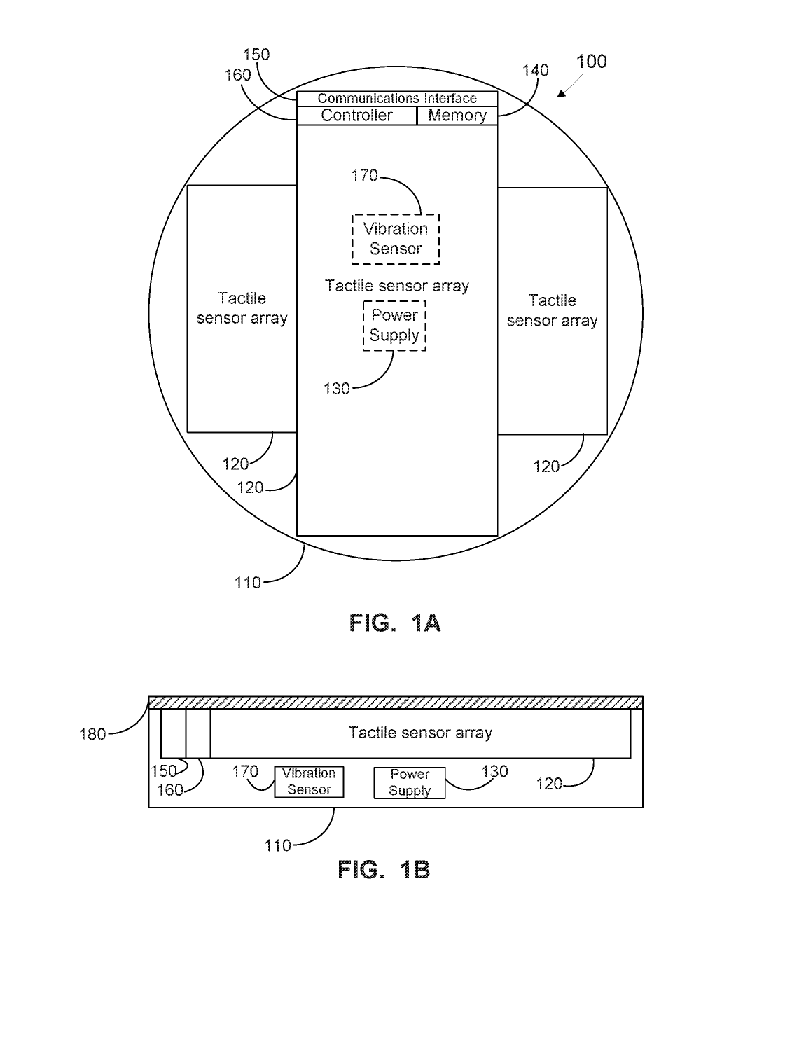

Turning now to FIG. 1A and FIG. 1B, we present stylized, plan (FIG. 1A) and side cutaway (FIG. 1B) depictions of an instrumented wafer 100, in accordance with embodiments herein. The instrumented wafer 100 may comprise a substrate 110 and at least one tactile sensor array 120 disposed on a top surface of the substrate.

The substrate 110 may comprise silicon, glass, or other material on or in which the other components of instrumented wafer 100 (described in more detail below) may be disposed. Desirably, the substrate 110 may comprise silicon, especially if the instrumented wafer 100 is intended for use in systems for the manufacture of semiconductor devices comprising silicon, silicon-on-insulator (SOI), silicon-germanium, or doped silicon wafers.

The at least one tactile sensor array 120 may comprise any sensor devices capable of sensing at least a first force impinging vertically on the instrumented wafer 100. In one embodiment, the at least one tactile sensor array 120 may comprise carbon nanotubes. Alternatively or in addition, the at least one tactile sensor array 120 may comprise a piezoelectric transducer. Alternatively or in addition, the at least one tactile sensor array 120 may comprise a pressure sensing ink pad.

The at least one tactile sensor array 120 may have a data acquisition frequency from about 100 Hz to about 1 KHz.

As stated above, the at least one tactile sensor array 120 may be disposed on a top surface of the substrate 110, such as is shown in FIG. 1B. In other words, a top surface of the at least one tactile sensor array 120 may be coplanar with the top surface of the substrate 110.

In addition to the first force impinging vertically on the instrumented wafer 100, in one embodiment, the at least one tactile sensor array 120 may be configured to sense both the first force and a second force impinging laterally or angularly on the top surface of the substrate 110. The second force may provide a shear or strain force to the instrumented wafer 100, which the at least one tactile sensor array 120 may sense.

In addition to the substrate 110 and the at least one tactile sensor array 120, the instrumented wafer 100 may further comprise one or more of a power supply 130; a memory 140; a communications interface 150; and a controller 160.

The power supply 130 may be any power supply known in the art. In one embodiment, the power supply 130 may comprise one or more thin film lithium ion batteries. Lithium-ion batteries may be suitable if the instrumented wafer 100 is to be used in methods of detecting forces from CMP pads, liquid sprays, and/or air dryers, which are generally applied at temperatures below about 140° C., as well as in semiconductor device manufacturing systems using such apparatus, both as described below. The power supply 130 of this embodiment may also comprise an inductive coil for wireless charging of the one or more batteries. In other embodiments, other sources of electrical power for the at least one tactile sensor array 120 and other components of the instrumented wafer 100 may be used.

The memory 140 may comprise any known data storage device. In one embodiment, the memory 140 comprises one or more non-volatile memory cells, such as flash memory cells. To reduce unnecessary battery drain, the data storage device of memory 140 may be chosen from devices that substantially only require electrical power to read from or write to memory, and do not require electrical power to maintain the state of memory.

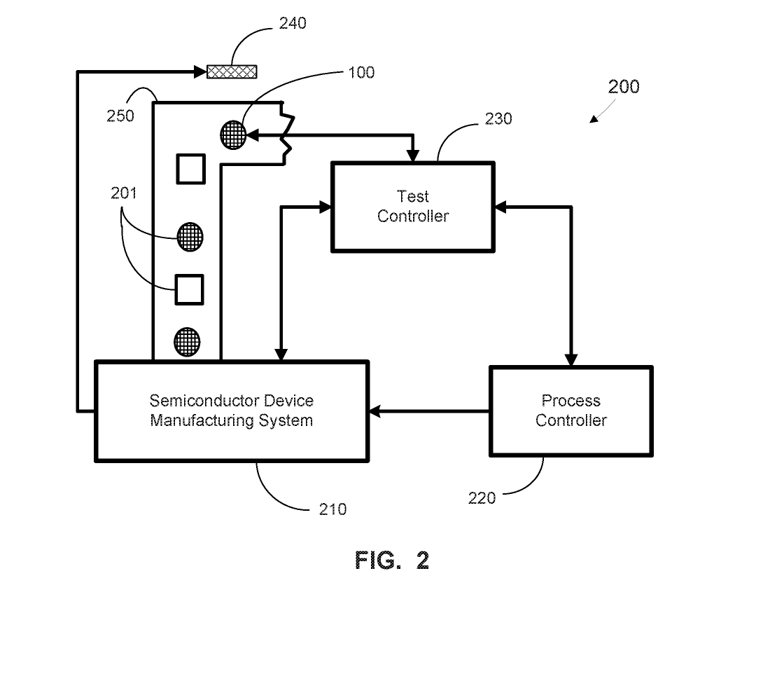

The communications interface 150 allows for communication from the instrumented wafer 100 to an external device, such as a test controller 230 of a system 200 shown in FIG. 2 and described in more detail below, and vice versa. The communication between the communications interface 150 and the external device may be wireless, e.g., it may comprise one or more of Bluetooth or WiFi, or it may be wired, e.g., it may comprise USB or other data transfer cable between appropriate ports of the communications interface 150 and the external device. Other wireless and wired communications protocols will be known to the person of ordinary skill in the art having the benefit of the present disclosure. In one embodiment, the communication is a wireless communication and the communications interface 150 is capable of transferring data gathered from the at least one tactile sensor array 120 to the external device without lag.

The controller 160 may be any microcontroller or processor, e.g., a microprocessor capable of being disposed within instrumented wafer 100. The controller 160 may receive data from the at least one tactile sensor array 120, perform any desired amplification, A/D conversion, buffering, and/or other data processing, and thence provide the processed data to the communications interface 150. Alternatively or in addition, the controller 160 may perform additional calculations on the processed data. The controller 160 may be capable of performing a responsive action based upon performing an analysis of the data from the sensors of the instrumented wafer 110. The responsive action may comprise at least one of providing a warning, providing feedback data for process adjustments, providing various sense signals, and/or wafer condition data.

In one embodiment, the controller 160 may be further configured to receive from the at least one tactile sensor array 120 data relating to at least a first force impinging vertically on the top surface of the substrate 110; determine whether the magnitude of first force is within a first range; and provide to an external device, via the communications interface 150, an indication whether the magnitude of first force is within the first range. Such an embodiment may be useful to provide rapid feedback to the external device and/or a user thereof to allow adjustment of CMP parameters, spraying parameters, drying parameters, etc. with reduced downtime of a semiconductor device manufacturing system comprising the instrumented wafer 100.

Alternatively or in addition, the instrumented wafer 100 may comprise one or more further components. In one embodiment, the instrumented wafer 100 may further comprise at least one vibration sensor 170 disposed within the substrate.

Any device capable of detecting vibration applied to the instrumented wafer 100 may be used as the at least one vibration sensor 170. In one embodiment, the at least one vibration sensor is selected from a microelectricalmechanical system (MEMS), an accelerometer, or a gyroscope.

Alternatively or in addition, in one embodiment, the instrumented wafer 100 may further comprise a chemical shield layer 180 disposed on the substrate 110 and the at least one tactile sensor array 120. The chemical shield layer 180 may be desired if the instrumented wafer 100 is intended to be exposed to harsh processing environments and/or steps, such as plasma etch chambers or other etching. For example, a chemical shield layer 180 may be a composite of different layers, such as a biaxially-oriented polyethylene terephthalate (BoPET) or metallized (BoPET) layer, a polyethylene (PE) layer, a metallic foil, and a sealant layer such as an ethylene-methacrylic acid ionomer. In one embodiment, the total thickness of the shield layer may range from 25 microns to 100 microns.

The instrumented wafer 100 may be of any shape or dimension. Desirably, for use in systems for the manufacture of a semiconductor device, the instrumented wafer 100 may have the same shape and size as wafers of the semiconductor device. In one embodiment, the instrumented wafer 100 is circular in top-down view (in three dimensions, a right cylinder) with a diameter of 8 inches or 12 inches and a thickness of less than about 1 mm, such as about 0.70 mm.

Further, in accordance with the present disclosure, the various components of the instrumented wafer 100 depicted in FIGS. 1A-1B may be placed in different locations on or in the instrumented wafer 100. In some embodiments, the placements of the sensors, power supply 130, controller 160, memory 140, communication interface 150 may be strategically positioned on the wafer such that they do not interfere with the particular processes that are to performed on that wafer.

In addition, the instrumented wafer 100 may further comprise certain routine structures, e.g., wiring between the at least one tactile sensor array 120 and the controller 160, between the controller 160 and the communications interface 150, etc.; positioning marks around the circumference of instrumented wafer 100 to assist in positioning the instrumented wafer 100 in a semiconductor device manufacturing system processing chamber, etc., which need not be described further.

Turning now to FIG. 2, a stylized depiction of a system 700 for fabricating a semiconductor device, in accordance with embodiments herein, is illustrated. The system 200 of FIG. 2 may comprise a semiconductor device manufacturing system 210 and a process controller 220. The semiconductor device manufacturing system 210 may manufacture semiconductor devices 100 based upon one or more instruction sets provided by the process controller 720. The semiconductor device manufacturing system 210 may comprise at least one apparatus configured to provide at least a first force impinging vertically on a workpiece (e.g., a semiconductor wafer 201). In one embodiment, the at least one apparatus may be a chemical mechanical polishing (CMP) pad 240. In other embodiments (not shown), the at least one apparatus may be a sprayer configured to spray water or other liquid on the workpiece, an air dryer configured to blow air over the workpiece, etc.

The system 200 may also comprise an instrumented wafer 100 as described above. Particularly, the instrumented wafer 100 comprises a substrate 110 and at least one tactile sensor array 120 disposed on a top surface of the substrate 110.

The system 200 may further comprise a test controller 230. The test controller 230 may be configured to apply, via a first apparatus (e.g., the CMP pad 240), at least the first force to the instrumented wafer 100. For example, in the depicted embodiment, the test controller 230 may relay an instruction to the semiconductor device manufacturing system 210 to deploy the CMP pad 240 to contact the top surface of the instrumented wafer 100. The test controller 230 may also be configured to receive, from the instrumented wafer 100, first data relating to at least the first force. Such first data may be collected by the at least one tactile sensor array 120 (and further, if present and so desired, the at least one vibration sensor 170), processed by the controller 160, and relayed via the communications interface 150 to the test controller 230.

Alternatively or in addition, the test controller 230 may be further configured to receive, from the instrumented wafer 100, an indication whether the magnitude of first force is within a first range, such as may be generated by the controller 160 as described above.

Regardless of the data received by the test controller 230 from the instrumented wafer 100, the test controller 230 may perform additional calculations to determine one or more properties of the first apparatus, and compare the determined property or properties with previously-specified values. By doing so, information useful to assess the functionality of the first apparatus (e.g., CMP pad 240) may be generated. The performance of system 200 may thus be managed. For example, based on data provided by the instrumented wafer 100 to the test controller 230, the system 200 may determine whether the first apparatus (e.g., CMP pad 240) is providing the desired amount of polishing, avoiding either dishing or incomplete polishing, and thereby determining whether process conditions should be modified and/or the first apparatus should be repaired or replaced.

In one embodiment, in addition to the CMP pad 240 or other first apparatus, the test controller 230 may be further configured to apply, via a second apparatus, such as conveyor 250, at least a second force to the instrumented wafer 200, wherein the second force impinges laterally or angularly on the top surface of the substrate 110; and receive, from the instrumented wafer 100, second data relating to at least the second force. Similarly to application by the test controller 230 of the first force via the first apparatus, the test controller 230 may apply the second force via the second apparatus by instructing the semiconductor device manufacturing system 210.

The test controller 230 may be configured to test one or more first apparatus, e.g., CMP pad 240, at any desired stage in processing. The test controller 230 may also be configured to bi-directionally communicate with the semiconductor device manufacturing system 210 and/or process controller 220 regarding various aspects of processing. For example, the process controller 220 may communicate with the test controller 230 to authorize or de-authorize placement of the instrumented wafer 100 in a processing chamber, and may receive data from the test controller 230 to updated process parameters for the first apparatus and/or delay or halt the operation of the system 200 to repair or replace the first apparatus.

The semiconductor device manufacturing system 210 may comprise various processing stations, such as etch process stations, photolithography process stations, CMP process stations using CMP pad 240, etc. One or more of the processing steps performed by the semiconductor device manufacturing system 210 may be controlled by the process controller 220. The process controller 220 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device manufacturing system 210 may produce semiconductor devices 201 (e.g., integrated circuits) on a medium, such as silicon wafers. The semiconductor device manufacturing system 210 may provide processed semiconductor devices 201 on a transport mechanism 250, such as a conveyor system. In some embodiments, the conveyor system may be sophisticated clean room transport systems that are capable of transporting semiconductor wafers. In one embodiment, the semiconductor device manufacturing system 210 may comprise a plurality of processing steps, e.g., the 1^{st} process step, the 2^{nd} process step, etc.

In some embodiments, the items labeled “201” may represent individual wafers, and in other embodiments, the items 201 may represent a group of semiconductor wafers, e.g., a “lot” of semiconductor wafers.

The system 200 may be capable of manufacturing various products involving various technologies. For example, the system 200 may produce devices of CMOS technology, Flash technology, BiCMOS technology, power devices, memory devices (e.g., DRAM devices), NAND memory devices, and/or various other semiconductor technologies.

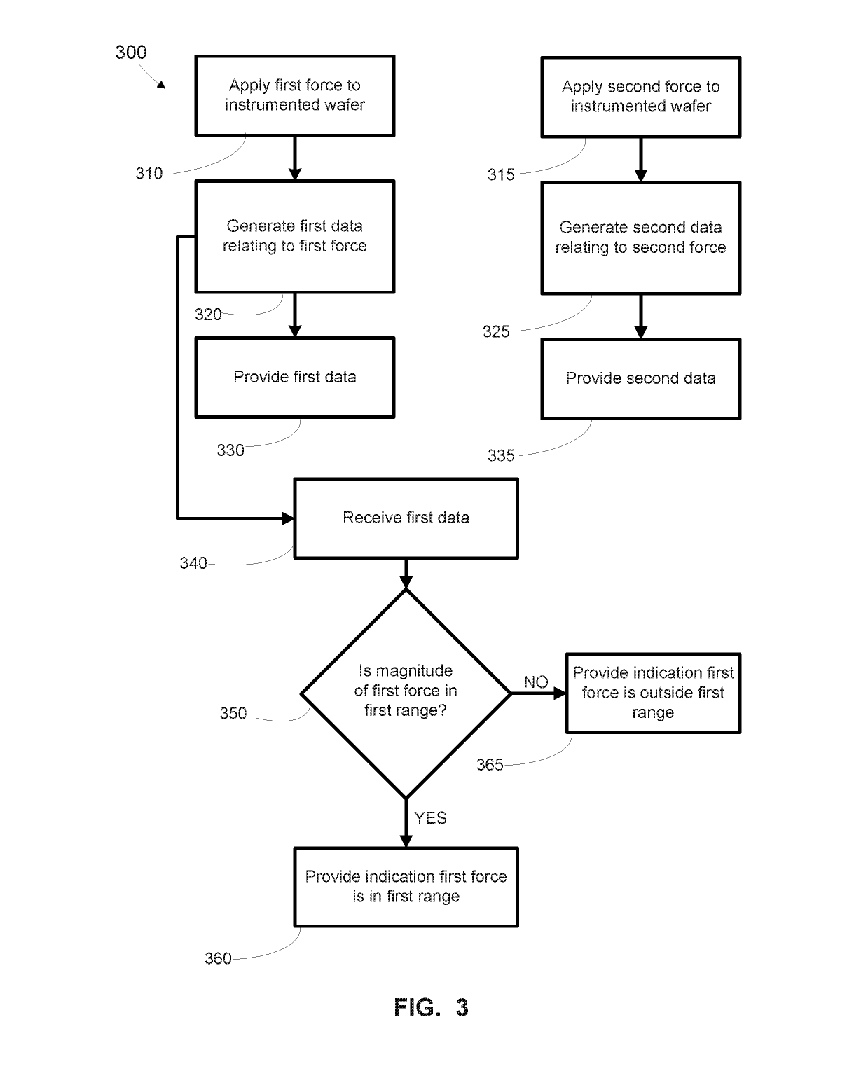

Turning to FIG. 3, a flowchart of a method 300 in accordance with embodiments herein is depicted. The method 300 may comprise applying (at 310) at least a first force (e.g., from a CMP pad 240) to an instrumented wafer 100 comprising a substrate 110, at least one tactile sensor array 120 disposed on a top surface of the substrate 110, a communications interface 150; and a controller 160, wherein the first force impinges vertically on the top surface of the substrate 110. The method 300 may then comprise generating (at 320), by the at least one tactile sensor array 120, first data relating to at least the first force. Thereafter, the method 300 may comprise providing (at 330) to an external device (e.g., test controller 230), by the communications interface 150, the first data.

In one embodiment, the method 300 may further comprise receiving (at 340), by the controller 160, the first data. The controller 160 may then determine (at 350), based at least in part on the first data, whether the magnitude of the first force is within a first range. If the magnitude of the first force is within the first range, the method 300 may comprise providing (at 360) to the external device (e.g., test controller 230), by the communications interface 160, an indication that the magnitude of the first force is within the first range. If the magnitude of the first force is outside the first range, the method 300 may comprise providing (at 365) to the external device (e.g., test controller 230), by the communications interface 160, an indication that the magnitude of the first force is outside the first range.

In one embodiment, the method 300 may further comprise applying (at 315) at least a second force to the instrumented wafer 100, wherein the second force impinges laterally or angularly on the top surface of the substrate 110; generating (at 325), by the at least one tactile sensor array 120, second data relating to at least the second force; and providing (at 335) to the external device (e.g., test controller 230), by the communications interface 160, the second data.

In some embodiments, different types of force data may be analyzed together to determine wafer condition and/or process parameter adjustments. In other embodiments, other wafer condition data, such as temperature, may also be analyzed in conjunction with the first data to determine whether wafer condition is outside an acceptable, predetermined range or values. In some embodiments, based on the indication that a force parameter (e.g., block 365) or other wafer condition parameter is outside a respective, predetermined thresholds or ranges, corrective action may be taken. The corrective action may be at least one of making a process adjustment, discarding a portion or all of a particular wafer, changing performance parameter specifications, etc.

The methods described above may be governed by instructions that are stored in a non-transitory computer readable storage medium and that are executed by, e.g., a processor in a computing device. Each of the operations described herein may correspond to instructions stored in a non-transitory computer memory or computer readable storage medium. In various embodiments, the non-transitory computer readable storage medium includes a magnetic or optical disk storage device, solid state storage devices such as flash memory, or other non-volatile memory device or devices. The computer readable instructions stored on the non-transitory computer readable storage medium may be in source code, assembly language code, object code, or other instruction format that is interpreted and/or executable by one or more processors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed is:

1. An instrumented wafer, comprising:
a substrate; and
at least one tactile sensor array disposed on a top surface of the substrate.

2. The instrumented wafer of claim 1, wherein the at least one tactile sensor array comprises carbon nanotubes.

3. The instrumented wafer of claim 1, wherein the at least one tactile sensor array comprises a piezoelectric transducer.

4. The instrumented wafer of claim 1, further comprising:
a power supply;
a memory;
a communications interface; and
a controller.

5. The instrumented wafer of claim 4, wherein the controller is configured to receive from the at least one tactile sensor array data relating to at least a first force impinging vertically on the top surface of the substrate; determine whether the magnitude of first force is within a first range; and provide to an external device, via the communications interface, an indication whether the magnitude of first force is within the first range.

6. The instrumented wafer of claim 1, further comprising:
at least one vibration sensor disposed within the substrate.

7. The instrumented wafer of claim 6, wherein the at least one vibration sensor is selected from a microelectricalmechanical system (MEMS), an accelerometer, or a gyroscope.

8. The instrumented wafer of claim 1, wherein the at least one tactile sensor array is configured to sense both a first force impinging vertically on the top surface of the substrate and a second force impinging laterally or angularly on the top surface of the substrate.

9. The instrumented wafer of claim 1, further comprising a chemical shield layer disposed on the substrate and the at least one tactile sensor array.

10. A method, comprising:
applying at least a first force to an instrumented wafer comprising a substrate, at least one tactile sensor array disposed on a top surface of the substrate, a communications interface; and a controller, wherein the first force impinges vertically on the top surface of the substrate;
generating, by the at least one tactile sensor array, first data relating to at least the first force;
providing to an external device, by the communications interface, the first data.

11. The method of claim 10, further comprising:
receiving, by the controller, the first data;
determining, by the controller, based at least in part on the first data, whether the magnitude of the first force is within a first range; and
providing to the external device, by the communications interface, an indication whether the magnitude of first force is within the first range.

12. The method of claim 10, wherein the at least one tactile sensor array comprises carbon nanotubes.

13. The method of claim 10, wherein the at least one tactile sensor array comprises a piezoelectric transducer.

14. The method of claim 10, wherein the applying further comprises applying at least a second force to the instrumented wafer, wherein the second force impinges laterally or angularly on the top surface of the substrate; the generating further comprises generating, by the at least one tactile sensor array, second data relating to at least the second force; and the providing further comprises providing to the external device, by the communications interface, the second data.

15. A system, comprising:
a process controller, configured to provide an instruction set for manufacture of the semiconductor device to a manufacturing system;
the manufacturing system, configured to manufacture the semiconductor device according to the instruction set, wherein the manufacturing system comprises at least one apparatus configured to provide at least a first force impinging vertically on a workpiece;
an instrumented wafer, comprising a substrate and at least one tactile sensor array disposed on a top surface of the substrate; and
a test controller, configured to:
apply, via a first apparatus, at least the first force to the instrumented wafer, and
receive, from the instrumented wafer, first data relating to at least the first force.

16. The system of claim 15, wherein the test controller is further configured to receive, from the instrumented wafer, an indication whether the magnitude of first force is within a first range.

17. The system of claim 15, wherein the at least one tactile sensor array comprises carbon nanotubes.

18. The system of claim 15, wherein the at least one tactile sensor array comprises a piezoelectric transducer.

19. The system of claim 15, wherein the test controller is further configured to apply, via a second apparatus, at least a second force to the instrumented wafer, wherein the second force impinges laterally or angularly on the top surface of the substrate; and receive, from the instrumented wafer, second data relating to at least the second force.

20. The system of claim 15, wherein the first apparatus is a chemical mechanical polishing (CMP) pad.
